(19) United States
(12) Patent Application Publication
(10) Pub. No.: US 2026/0280502 A1
(43) Pub. Date: Sep. 17, 2026

(54) AMPLIFIER CONFIGURED TO PROVIDE SUBSTANTIALLY CONSTANT GAIN FOR WIDE INPUT COMMON MODE RANGE

(71) Applicant: QUALCOMM Incorporated, San Diego, CA (US)

(72) Inventors: John ABCARIUS, San Diego, CA (US); Andrew WEIL, San Diego, CA (US); Sungmin OCK, San Diego, CA (US)

(21) Appl. No.: 19/076,492

(22) Filed: Mar. 11, 2025

(51) Int. Cl. H03F 3/45

(52) U.S. Cl. CPC H03F 3/45269

(57) ABSTRACT

An amplifier, including: an output circuit; input differential NFETs including drains coupled to the output circuit, and gates configured to receive positive and negative components of an input differential signal, respectively; a current source NFET including a drain coupled to sources of the input differential NFETs, respectively, and a gate coupled to the output circuit and configured to receive a first bias voltage; a current source PFET including a gate configured to receive a second bias voltage; input differential PFETs including sources coupled to a drain of the current source PFET, and gates configured to receive the positive and negative components of the input differential signal, respectively; a pair of current source NFETs including drains coupled to the output circuit and to drains of the input differential PFETs, respectively; and a control circuit including an input coupled to the current source PFET and an output coupled to gates of the first pair of current source NFETs.

### FIELD

This disclosure relates generally to amplifiers, and in particular, to an amplifier configured to provide substantially constant gain for wide input common mode range.

### BACKGROUND

A low dropout (LDO) voltage regulator may be configured to provide a regulated supply voltage to a particular load, such as a voltage controlled oscillator (VCO). The load, such as the VCO, may be used in various operating modes that may require significantly different regulated voltages. Accordingly, the regulated supply voltage generated by the LDO voltage regulator may have a wide voltage range. The LDO voltage regulator typically includes an operational amplifier for driving a pass field effect transistor (FET) to generate the regulated supply voltage. The wide voltage range for the regulated supply voltage may impose a wide range common mode voltage associated with an input differential voltage of the operational amplifier.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an amplifier. The amplifier, includes: an output circuit; a pair of input differential n-channel field effect transistors (NFETs) including drains coupled to the output circuit, and gates configured to receive positive and negative components of an input differential signal, respectively; a current source NFET including a drain coupled to sources of the input differential NFETs, and a gate coupled to the output circuit and configured to receive a first bias voltage; a current source p-channel field effect transistor (PFET) including a gate configured to receive a second bias voltage; a pair of input differential PFETs including sources coupled to a drain of the current source PFET, and gates configured to receive the positive and negative components of the input differential signal, respectively; a first pair of current source NFETs including drains coupled to the output circuit and to drains of the input differential PFETs, respectively; and a control circuit including an input coupled to the current source PFET and an output coupled to gates of the first pair of current source NFETs, respectively.

Another aspect of the disclosure relates to an amplifier. The amplifier, includes: an output circuit; a current source p-channel field effect transistor (PFET) including a gate coupled to the output circuit and configured to receive a first bias voltage; a pair of input differential PFETs including sources coupled to a drain of the current source PFET, drains coupled to the output circuit, and gates configured to receive positive and negative components of an input differential signal, respectively; a first pair of current source PFETs; a pair of input differential n-channel field effect transistors (NFETs) including drains coupled to drains of the first pair of current source PFETs, respectively, and gates configured to receive the positive and negative components of the input differential signal, respectively; a current source NFET including a gate configured to receive a second bias voltage, and a drain coupled to sources of the pair of input differential NFETs, respectively; and a control circuit including an input coupled to the current source NFET and an output coupled to gates of the first pair of current source PFETs, respectively.

Another aspect of the disclosure relates to a method. The method includes: amplifying an input differential signal using a first pair of input differential field effect transistor (FETs) to generate an output signal at an output circuit; amplifying the input differential signal using a second pair of input differential FETs to generate the output signal at the output circuit; sensing a current flowing into or out of the second pair of input differential FETs from or to a first current source, respectively; and controlling a pair of currents flowing out of or into the first pair of input differential FETs and into or out of a first pair of current sources based on the sensed current, respectively, to reduce currents flowing through the output circuit to or from the first pair of current sources.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example phase locked loop (PLL) in accordance with an aspect of the disclosure.

FIG. 2 illustrates a schematic diagram of an example low dropout (LDO) voltage regulator in accordance with another aspect of the disclosure.

FIG. 3A illustrates a schematic diagram of an example amplifier in accordance with another aspect of the disclosure.

FIG. 3B illustrates a graph of an example direct current (DC) gain versus input common mode voltage VinCM of an input differential signal associated with the amplifier of FIG. 3A in accordance with another aspect of the disclosure.

FIG. 3C illustrates a graph of an example drain current (Id) versus drain-to-source voltage (Vds) associated with an output field effect transistor (FET) of the amplifier of FIG. 3A in accordance with another aspect of the disclosure.

FIG. 4A illustrates a schematic diagram of another example amplifier in accordance with another aspect of the disclosure.

FIG. 4B illustrates a graph of an example direct current (DC) gain versus input common mode voltage VinCM of an input differential signal associated with the amplifier of FIG. 4A in accordance with another aspect of the disclosure.

FIG. 5 illustrates a schematic diagram of another example amplifier in accordance with another aspect of the disclosure.

FIG. 6 illustrates a schematic diagram of another example amplifier in accordance with another aspect of the disclosure.

FIG. 7 illustrates a schematic diagram of another example amplifier in accordance with another aspect of the disclosure.

FIG. 8 illustrates a schematic diagram of another example amplifier in accordance with another aspect of the disclosure.

FIG. 9 illustrates a schematic diagram of another example amplifier in accordance with another aspect of the disclosure.

FIG. 10 illustrates a flow diagram of an example method of amplifying an input differential signal to generate an output signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

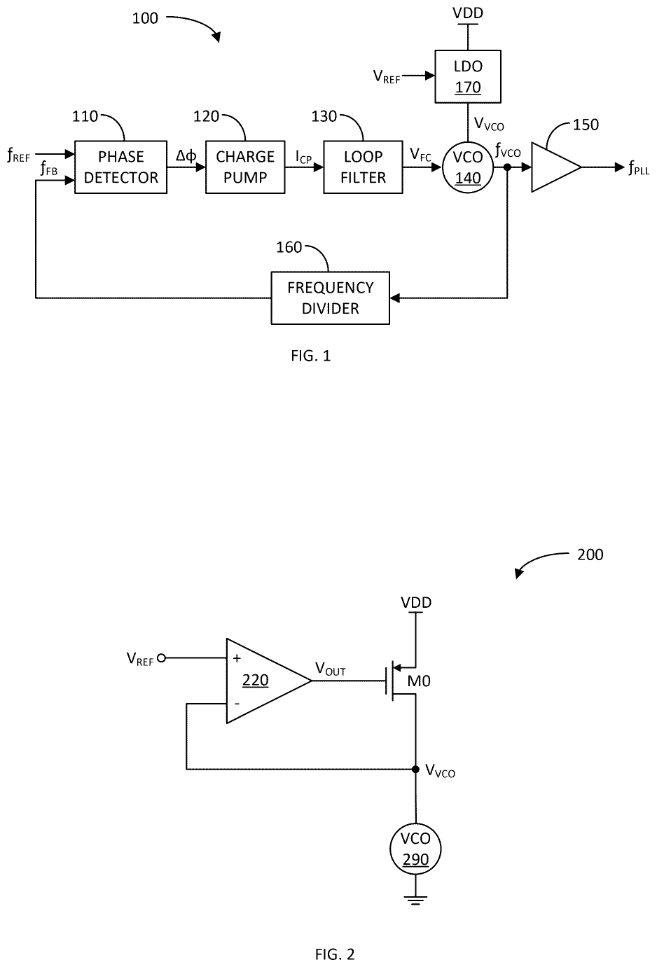

FIG. 1 illustrates a block diagram of an example phase locked loop (PLL) 100 in accordance with an aspect of the disclosure. The PLL 100 serves as an example to which a low dropout (LDO) voltage regulator provides a regulated voltage. The PLL 100 includes a phase detector 110, a charge pump 120, a loop filter 130, a voltage controlled oscillator (VCO) 140, a buffer 150, and a frequency divider 160. Additionally, the PLL 100 includes a low dropout (LDO) voltage regulator 170.

The phase detector 110 is configured to generate a phase error signal Δφ based on a phase difference between a reference clock signal f_{REF} and a feedback clock signal f_{fB}. The charge pump 120 is configured to generate a current signal I_{CP} based on the phase error signal Δφ. The loop filter 130 is configured to filter (e.g., low pass filter) the current signal I_{CP} to generate a frequency-control voltage signal V_{FC} for the VCO 140. The VCO 140 is configured to generate a VCO clock signal f_{VCO} whose frequency is controlled by the frequency-control voltage signal V_{FC}. The frequency divider 160 is configured to frequency divide the VCO clock signal f_{VCO} to generate the feedback clock signal f_{fB}. The buffer 150 is configured to buffer the VCO clock signal f_{VCO} to generate an output clock f_{PLL} of the PLL 100.

As shown, the LDO voltage regulator 170 is coupled between a power or voltage rail VDD and the VCO 140. The LDO voltage regulator 170 is configured to generate a regulated supply voltage V_{VCO} for supplying power to the VCO 140. The LDO voltage regulator 170 may generate the regulated supply voltage V_{VCO} based on a substantially temperature-stable reference voltage V_{REF} (e.g., a bandgap voltage). The LDO voltage regulator 170 substantially isolates the VCO 140 from noise present on the voltage rail VDD (e.g., due to high speed and current demanding switching circuitry coupled to the voltage rail VDD). As a result, the VCO 140 is able to generate the VCO clock signal f_{VCO} with substantially less phase noise.

The PLL 100 may be used to provide the PLL clock signal f_{PLL} for controlling the speed of operation of various circuits, such as one or more cores or sub-cores of a system on chip (SOC). In certain high-performance modes, such circuits may be operated at a relatively high speed, for example, to process data in a relatively fast manner. In certain low-performance modes (e.g., sleep or lower power), such circuits may be operated at a relatively low speed to consume less power while optionally performing some low speed operations. Accordingly, the frequency of the PLL clock signal f_{PLL} may vary significantly between such high and low performance modes. And, as a consequence, the VCO supply voltage V_{VCO} may be varied between relatively high voltage to relatively low voltage based on the high to low performance operation of the PLL 100, respectively.

FIG. 2 illustrates a schematic diagram of an example low dropout (LDO) voltage regulator 200 in accordance with another aspect of the disclosure. The LDO voltage regulator 200 may be an example implementation of the LDO 170 of PLL 100 previously discussed. The LDO voltage regulator 200 includes an amplifier (e.g., operational amplifier) 220 and a pass field effect transistor (FET) MO (e.g., of a p-channel type, but could also be of an n-channel type).

The amplifier 220 includes a first (e.g., positive) input configured to receive a reference voltage VREF, a second (e.g., negative) input that may be coupled directly (as shown) (or indirectly via a resistor or voltage divider) to an output of the LDO voltage regulator 200, and an output coupled to a gate of the pass FET MO. The pass FET MO is coupled between an upper voltage rail VDD and the output of the LDO voltage regulator 200. The VCO 290 (and/or other type of load) may be coupled between the output of the LDO voltage regulator 200 and a lower voltage rail (e.g., ground).

Via negative feedback, the amplifier 220 generates an output voltage V_{OUT} to control (via the gate voltage of) the pass FET MO such that the VCO supply voltage V_{VCO} is substantially equal to or related (based on the resistor or voltage divider) to the reference voltage V_{REF}. As previously discussed, the VCO supply voltage V_{VCO} may vary significantly depending on the performance mode of the VCO 290. Accordingly, the input common mode voltage of an input differential signal (e.g., V_{REF}/V_{VCO}) of the amplifier 220 may likewise vary significantly to achieve the desired variation of the VCO supply voltage V_{VCO}.

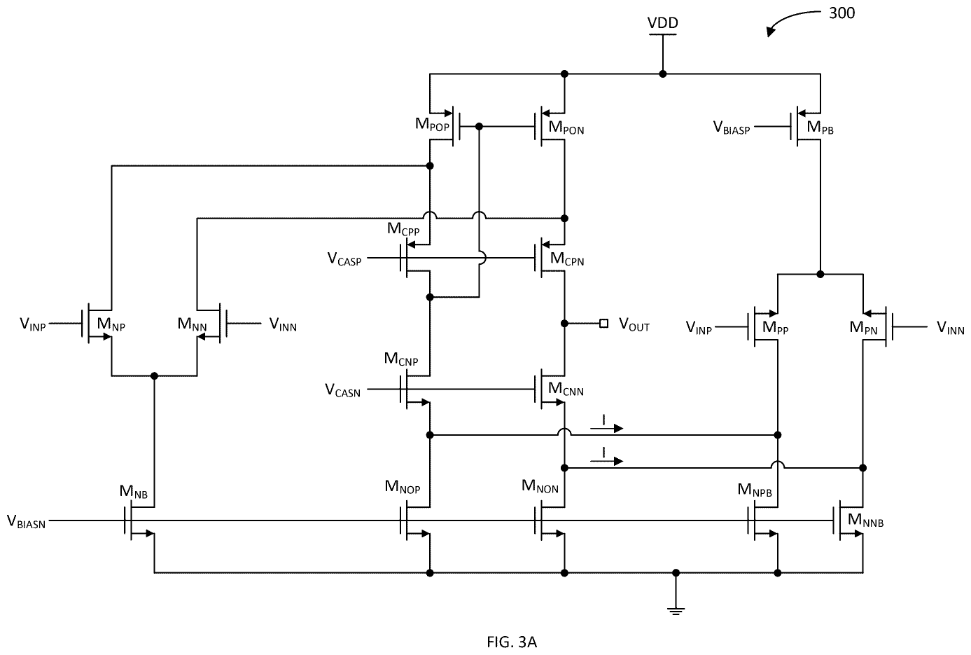

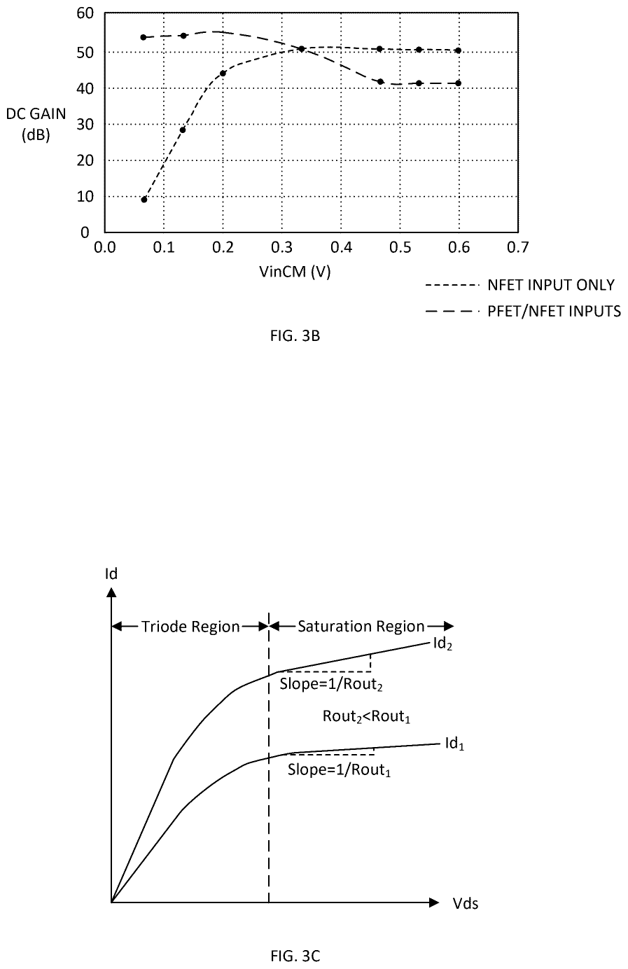

FIG. 3A illustrates a schematic diagram of an example amplifier 300 in accordance with another aspect of the disclosure. The amplifier 300 may be an example implementation of the amplifier 220 of the LDO voltage regulator 200. The amplifier 300 includes a folded cascode amplifier configuration including input differential n-channel field effect transistors (NFETs) M_{NP} and M_{NN}, a current source (or sink) NFET M_{NB}, and an output circuit including current mirror p-channel field effect transistors (PFETs) M_{POP} and M_{PON}, a pair of cascode PFETs M_{CPP} and M_{CPN}, a pair of cascode NFETs M_{CNP} and M_{CNN}, and a pair of current source (or sink) NFETs M_{NOP} and M_{NON}.

The current mirror PFETs M_{POP} and M_{PON} include sources coupled to an upper voltage rail VDD, gates coupled together, and drains coupled to drains of the input differential NFETs M_{NP} and M_{NN}, respectively. The input differential NFETs M_{NP} and M_{NN} include gates configured to receive a positive component V_{INP} and a negative component V_{INN} of an input differential signal V_{INP}/V_{INN}, respectively. The input differential NFETs M_{NP} and M_{NN} include sources coupled to a drain of current source NFET M_{NB}. The current source NFET M_{NB} includes a gate configured to receive an NFET current source bias voltage V_{BIASN} for setting/controlling a substantially constant current through the current source NFET M_{NB}, and a source coupled to a lower voltage rail (e.g., ground).

The cascode PFETs M_{CPP} and M_{CPN} include sources coupled to drains of the current mirror PFETs M_{POP} and M_{PON}, respectively. The cascode PFETs M_{CPP} and M_{CPN} include gates configured to receive a PFET cascode bias voltage V_{CASP}. The cascode PFETs M_{CPP} and M_{CPN} include drains coupled to drains of the cascode NFETs M_{CNP} and M_{CNN}, respectively. The coupled-together drains of cascode FETs M_{CPP} and M_{CNP} may be coupled to the gates of the current mirror PFETs M_{POP} and M_{PON}. The output of the amplifier 300 may be taken off the coupled-together drains of the cascode FETs M_{CPN} and M_{CNN}, respectively. The output of the amplifier 300 is configured to produce the output signal V_{OUT} (e.g., for driving the gate of the pass FET MO of the LDO voltage regulator 200).

The cascode NFETs M_{CNP} and M_{CNN} include gates configured to receive a NFET cascode bias voltage V_{CASN}. The cascode NFETs M_{CNP} and M_{CNN} include sources coupled to drains of the NFET current source NFETs M_{NOP} and M_{NON}, respectively. The NFET current source NFETs M_{NOP} and M_{NON} include gates coupled to the gate of the current source NFET M_{NB} to also receive the NFET current source bias voltage V_{BIASN}. Similarly, the NFET current source bias voltage V_{BIASN} configures the NFET current source NFETs M_{NOP} and M_{NON} to generate a substantially constant current. The NFET current source NFETs M_{NOP} and M_{NON} include sources coupled to the lower voltage rail (e.g., ground).

If the input differential signal V_{INP}/V_{INN} has a relatively high common mode voltage level, the input differential NFETs M_{NP} and M_{NN} are significantly turned on (e.g., the voltage drop across them is relatively small) to produce a drain voltage for the current source NFET M_{NB} that is high enough for it operate in the saturation region and serve as an effective current source for the input differential NFETs M_{NP} and M_{NN}. If, on the other hand, the input differential signal V_{INP}/V_{INN} has a relatively low common mode voltage level, the input differential NFETs M_{NP} and M_{NN} are not significantly turned on (e.g., the voltage drop across them is relatively large), which causes the drain voltage for the current source NFET M_{NB} to be relatively low such that it operates in the triode region. In such case, the current source NFET M_{NB} collapses and stops operating as an effective current source; thereby, adversely impacting the operation of the amplifier 300.

Accordingly, to deal with a wide input common mode voltage swing (e.g., low and high), the amplifier 300 further includes a pair of input differential PFETs M_{PP} and M_{PN} and related circuitry. More specifically, the amplifier 300 includes a current source PFET M_{PB}, the pair of input differential PFETs M_{PP} and M_{PN}, and a pair of current source (or sink) NFETs M_{NPB} and M_{NNB}. The current source PFET M_{PB} includes a source coupled to the upper voltage rail VDD, a gate configured to receive a PFET current source bias voltage V_{BIASP}, and a drain coupled to sources of the input differential PFETs M_{PP} and M_{PN}, respectively. The input differential PFETs M_{PP} and M_{PN} include gates configured to receive the positive component V_{INP} and the negative component V_{INN} of the input differential signal V_{INP}/V_{INN}, respectively.

The input differential PFETs M_{PP} and M_{PN} include drains coupled to drains of the current source NFETs M_{NPB} and M_{NNB}, respectively. The current source NFETs M_{NPB} and M_{NNB} include gates coupled to gates of current source NFETs M_{NB}, M_{NOP}, and M_{NON} to also receive the NFET current source bias voltage V_{BIASN}. Similarly, the NFET current source bias voltage V_{BIASN} configures each of the current source NFETs M_{NPB} and M_{NNB} to generate a substantially constant current. The current source NFETs M_{NPB} and M_{NNB} include sources coupled to the lower voltage rail (e.g., ground). The sources of the cascode NFETs M_{CNP} and M_{CNN} of the output circuit are also coupled to the drains of the current source NFETs M_{NPB} and M_{NNB}, respectively. The operation of the amplifier 300 is explained as follows.

FIG. 3B illustrates a graph of an example direct current (DC) gain versus input common mode voltage VinCM of the input differential signal V_{INP}/V_{INN} associated with the amplifier 300 in accordance with another aspect of the disclosure. The horizontal axis of the graph represents the input common mode voltage VinCM in Volt (V) ranging from 0.0V to 0.7V. The vertical axis of the graph represents the DC gain of the amplifier 300 (e.g., DC gain=V_{OUT}/VinCM) ranging from zero (0) decibel (dB) to 60 dB.

The graph depicts the DC gain versus input common mode voltage VinCM response of the amplifier 300 (represented as a short-dashed line) if the input differential PFETs MPP and M_{PN} and related circuitry were not present in the amplifier 300 (e.g., only the input differential NFETs M_{NP}/M_{NN}). As the graph illustrates, and as previously discussed, if the input common mode voltage VinCM is relatively high (e.g., at or above 0.2V), the amplifier 300 has a relatively high DC gain (e.g., about 45 dB to 50 dB). This is because the input differential NFETs M_{NP}/M_{NN} are sufficiently turned on to provide a sufficient drain voltage for the current source NFET M_{NB} to allow it to operate in the saturation region and effectively as a current source. If the input common mode voltage VinCM is relatively low (e.g., below 0.2V), the amplifier 300 has a relatively low DC gain (e.g., about 10 dB to 40 dB). This is because the input differential NFETs M_{NP}/M_{NN} are sufficiently turned off to produce a significant voltage drop across them that results in a lower drain voltage of the current source NFET M_{NB}. This causes the current source NFET M_{NB} to operate in the triode region, where it no longer operates effectively as a current source.

The graph also depicts the DC gain versus input common mode voltage VinCM response of the amplifier 300 (represented as a long-dashed line) if the input differential PFETs M_{PP} and M_{PN} and related circuitry were present in the amplifier 300 (e.g., both the input differential NFETs M_{NP}/M_{NN} and PFETs MPP/M_{PN} are present). As the graph illustrates, if the input common mode voltage VinCM is relatively low (e.g., below 0.3V), the amplifier 300 has a relatively high DC gain (e.g., about 50 dB to 55 dB) due to the input differential PFETs M_{PP} and M_{PN} being turned on sufficiently to produce a sufficiently low drain voltage for the current source PFET M_{PB} to allow it to operate in the saturation region and effectively as a current source. If the input common mode voltage VinCM is relatively high (e.g., at or above 0.3V), the amplifier 300 has a relatively high DC gain (e.g., about 42 dB to 50 dB). This is because, as previously discussed, the input differential NFETs M_{NP}/M_{NN} are sufficiently turned on to provide a sufficient drain voltage for the current source NFET M_{NB} to allow it to operate in the saturation region and effectively as a current source.

However, as the graph also illustrates, the DC gain of the amplifier 300 drops by about 10 dB above an input common mode voltage VinCM increases of 0.3V, with a total DC gain variation of 15 dB across the input common mode voltage VinCM range of 0.1V to 0.6V. This is due to the effects the input differential PFETs MPP/M_{PN} have on the output circuit when they are effectively turned off due to a high input common mode voltage VinCM. That is, when the input differential PFETs MPP/M_{PN} are effectively turned off due to a relatively high input common mode voltage VinCM, the current through the input differential PFETs MPP/M_{PN} reduces or is substantially nil. The current source NFETs M_{NPB} and M_{NNB}, being biased for sourcing a substantially constant current, pull currents I from the output circuit to maintain the constant current. The current source NFETs M_{NPB} and M_{NNB} pulling current I from the output circuit increases the current or current density through the output cascode FETs M_{CPP}, M_{CPN}, M_{CNP}, and M_{CNN}. As discussed in more detail as follows, the increase in the current or current density in the output cascode FETs M_{CPP}, M_{CPN}, M_{CNP}, and M_{CNN} reduces the DC gain of the amplifier 300.

FIG. 3C illustrates a graph of an example drain current (Id) versus drain-to-source voltage (Vds) associated with an output field effect transistor (FET) (e.g., M_{CPP}, M_{CPN}, M_{CNP}, and M_{CNN}) of the amplifier 300 in accordance with another aspect of the disclosure. The horizontal axis of the graph represents the drain-to-source voltage Vds of the output FET, and the vertical axis of the graph represents the drain current Ids of the output FET.

The graph includes two (2) drain current Id versus drain-to-source voltage Vds responses of the output FET for different drain current or current densities Id₁ and Id₂. In the saturation region, where the output FET operates, the output resistance Rout associated with the output FET is inversely related to the slope of the Id-Vds responses. For the lower drain current or current density Id₁, the slope of the Id-Vds response in the saturation region is relatively small. For the higher drain current or current density Id₂, the slope of the Id-Vds response in the saturation region is relatively high. Accordingly, as the output resistance Rout is inversely related to the slope of the Id-Vds response, the output resistance Rout₂ associated with the higher current density Id₂ is less than the output resistance Rout₁ associated with the lower current density Id₁ (e.g., Rout₂<Rout₁).

As the DC gain of the amplifier 300 is related to the transconductance gain gm of the output FET multiplied by its output resistance Rout (e.g., DC gain=gm*Rout), the lower Rout₂ associated with the higher current density Id₂ results in a lower DC gain. Accordingly, with reference again to FIG. 3A, the current I pulling by the current source NFETs M_{NPB} and M_{NNB} when the input common mode voltage VinCM is relatively high (e.g., above 0.3V) causes the current density in the output cascode FETs M_{CPP}, M_{CPN}, M_{CNP}, and M_{CNN} to increase, which results in their output resistance Rout to decrease, which, in turn, results in a lowering of the DC gain of the amplifier 300 (e.g., by 10 dB as the input common mode voltage VinCM increases from 0.3V to 0.6V, as shown in FIG. 3B).

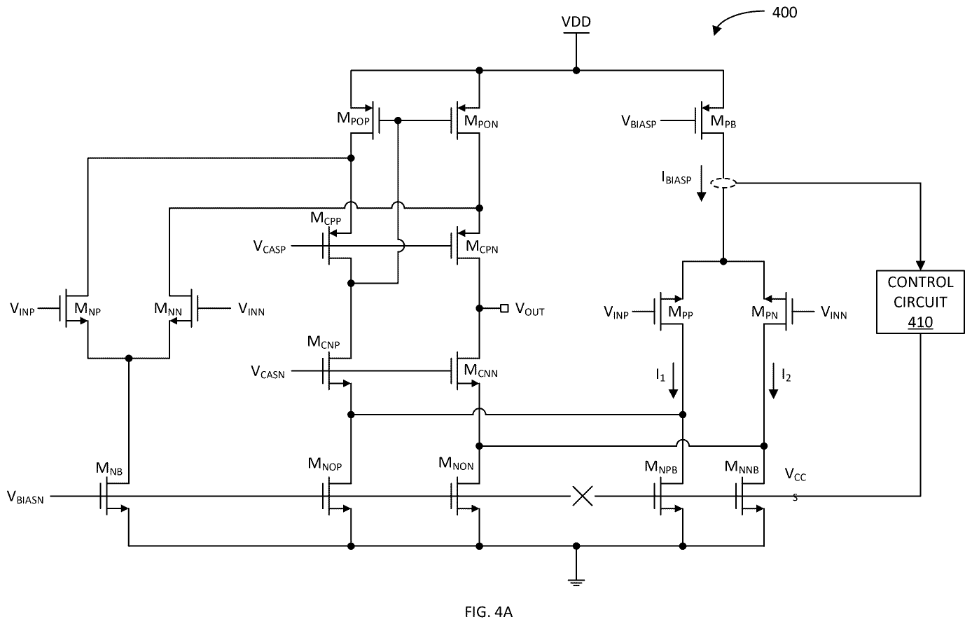

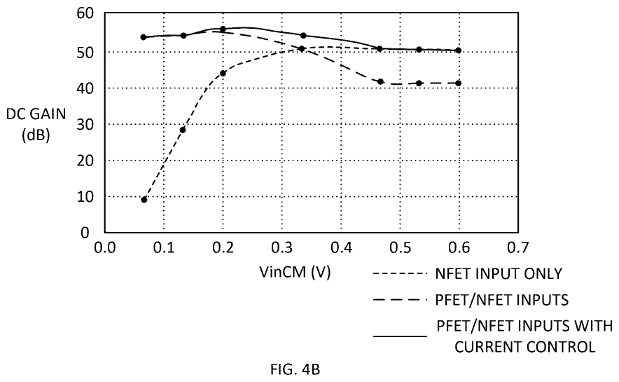

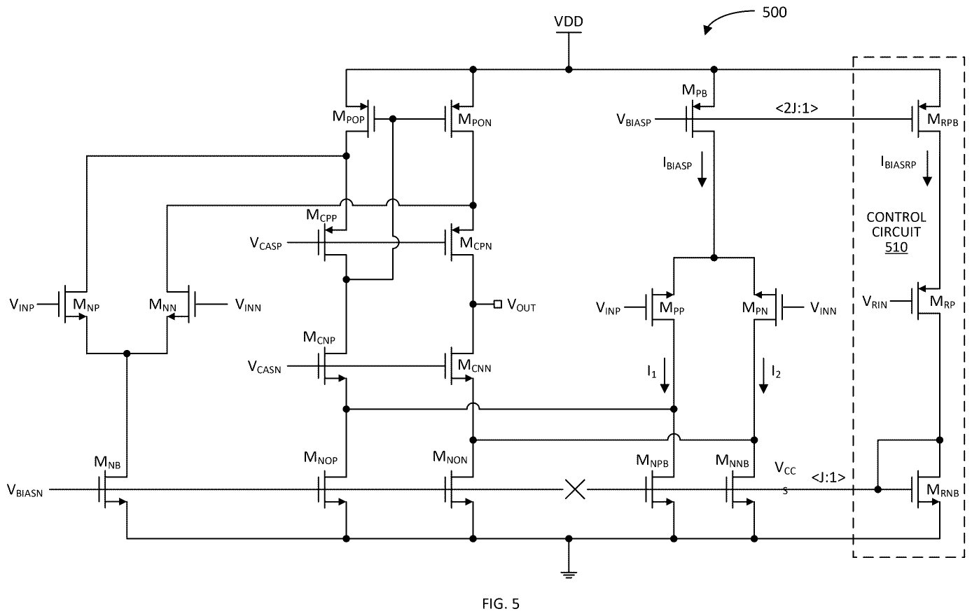

FIG. 4A illustrates a schematic diagram of another example amplifier 400 in accordance with another aspect of the disclosure. The amplifier 400 may also be an example implementation of the amplifier 220 of the LDO voltage regulator 200. The amplifier 400 is similar to amplifier 300 and includes many of the same/similar elements as indicated by the same reference identifiers.

The amplifier 400 differs from amplifier 300 in a couple of manners: (1) the gates of the current source NFETs M_{NPB} and M_{NNB} are no longer coupled to the gates of the current source NFETs M_{NB}, M_{NOP}, and M_{NON}; and thereby, do not receive and are not controlled by the NFET current source bias voltage V_{BIASN}; and (2) the amplifier 400 further includes a control circuit 410 including an input coupled to and configured to sense the bias current I_{BIASP} flowing through the current source PFET M_{PB}, and an output coupled to the gates of the current source NFETs M_{NPB} and M_{NNB}.

The control circuit 410 is configured to control currents I₁ and I₂ flowing through the current source NFETs M_{NPB} and M_{NNB} (via a control gate voltage V_{CCS}) based on the bias current I_{BIASP} flowing through the current source PFET M_{PB} (e.g., where the currents I₁ and I₂ flowing through the current source NFETs M_{NPB} and M_{NNB} are substantially equal to each other, and their sum is substantially equal to the bias current I_{BIASP} flowing through the current source PFET M_{PB} (e.g., I₁=I₂=I_{BIASP}/2→I₁+I₂=I_{BIASP}). In such case, when the input common mode voltage VinCM is relatively high, and the bias current I_{BIASP} flowing through the current source PFET M_{PB} and into the input differential PFETs M_{PP} fand MPN is relatively small, the control circuit 410 generates the control voltage V_{CCS} so that the currents I₁ and I₂ flowing through the current source NFETs M_{NPB} and M_{NNB} track the bias current I_{BIASP}. As a result, the current source NFETs M_{NPB} and M_{NNB} do not substantially pull any current from the output FETs M_{CPP}, M_{CPN}, M_{CNP}, and M_{CNN} so as not to substantially affect the output resistance Rout; and therefore, the DC gain of the amplifier 400.

FIG. 4B illustrates a graph of an example direct current (DC) gain versus input common mode voltage VinCM of the input differential signal V_{INP}/V_{INN} associated with the amplifier 400 in accordance with another aspect of the disclosure. The graph is substantially the same as the graph depicted in FIG. 3B except that it further includes the DC gain versus VinCM response associated with the amplifier 400 as shown as a solid line. As shown, the DC gain versus VinCM response is substantially constant over a wide range of VinCM (e.g., from less than 0.1V to 0.6V) only varying by about 5 dB due to the current source NFETs M_{NPB} and M_{NNB} not drawing substantially any current from the output circuit (e.g., FETs M_{CPP}, M_{CPN}, M_{CNP}, and M_{CNN}).

FIG. 5 illustrates a schematic diagram of another example amplifier 500 in accordance with another aspect of the disclosure. The amplifier 500 may be another example implementation of the amplifier 220 of the LDO voltage regulator 200. The amplifier 500 is similar to amplifier 400 and includes many of the same/similar elements as indicated by the same reference identifiers. The amplifier 500 provides an example implementation of the control circuit 410 of amplifier 400.

In particular, the amplifier 500 includes a control circuit 510 including a replica current source PFET M_{RPB}, a replica input PFET M_{RP}, and a replica (diode-connected) current source NFET M_{RNB} coupled in series between the upper voltage rail VDD and the lower voltage rail (e.g., ground). More specifically, the replica current source PFET M_{RPB} includes a source coupled to the upper voltage rail VDD, a gate coupled to the gate of the current source PFET M_{PB}, and a drain coupled to a source of the replica input PFET M_{RP}. The replica input PFET M_{RP} includes a gate configured to receive a replica input voltage V_{RIN}, and a drain coupled to the drain/gate of the replica (diode-connected) current source NFET M_{RNB}. The drain/gate of the replica (diode-connected) current source NFET M_{RNB} is coupled to the gates of the current source NFETs M_{NPB} and M_{NNB}. The replica (diode-connected) current source NFET M_{RNB} includes a source coupled to the lower voltage rail (e.g., ground).

The current source PFET M_{PB} and replica current source PFET M_{RPB} form a current mirror to generate a replica bias current I_{BIASRP} based on the bias current I_{BIASP}. For example, the channel width to channel length ratio (W/L) of the current source PFET MPB may be substantially 2J times larger than the W/L of the replica current source PFET M_{RPB}. In such case, the replica bias current I_{BIASRP} is substantially equal to 1/2J*IBIASP (e.g., the current mirror has a current gain of 1/2J). The replica input voltage V_{RIN} may be the positive component V_{INP} of the input differential signal V_{INP}/V_{INN}, the negative component V_{INN} of the input differential signal V_{INP}/V_{INN}, or substantially the common mode voltage VinCM associated with the input differential signal V_{INP}/V_{INN} (e.g., VinCM=(V_{INP}+V_{INN})/2).

The replica (diode-connected) current source NFET M_{RNB} and the current source NFETs M_{NPB} and M_{NNB} also form a current mirror to generate currents I₁ and I₂ based on the replica bias current IBIASRP. The W/L of each of the current source NFETs M_{NPB} and M_{NNB} may be substantially J times larger than the W/L of the replica (diode-connected) current source NFET M_{RNB}. In such case, the currents I₁ and I₂ are each substantially equal to 1/J*I_{BIASRP} (e.g., the current mirror has a current gain of J). Accordingly, based on the aforementioned current mirror configurations, the currents I₁ and 12 are each substantially equal to I_{BIASP}/2 (e.g., I₁=I₂=J*I_{BIASRP}=J*(1/2J*I_{BIASP})=I_{BIASP}/2). As discussed with reference to amplifier 400, the currents I₁ and I₂ tracking the bias current I_{BIASP} cause the current source NFETs M_{NPB} and M_{NNB} to not substantially pull any current from the output FETs M_{CPP}, M_{CPN}, M_{CNP}, and M_{CNN} so as not to substantially affect the output resistance Rout; and therefore, the DC gain of the amplifier 500.

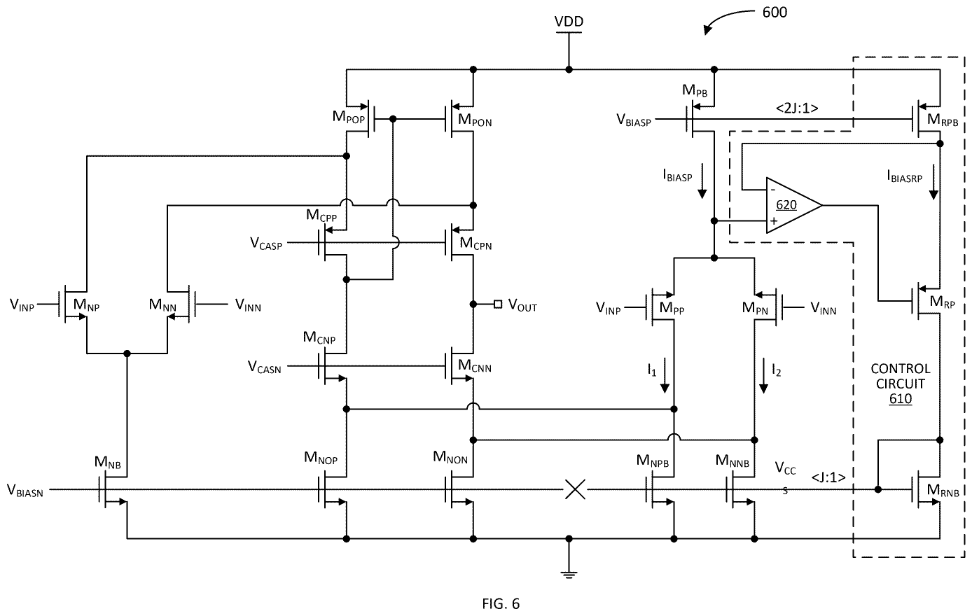

FIG. 6 illustrates a schematic diagram of another example amplifier 600 in accordance with another aspect of the disclosure. The amplifier 600 may be another example implementation of the amplifier 220 of the LDO voltage regulator 200. The amplifier 600 is similar to amplifier 500 and includes many of the same/similar elements as indicated by the same reference identifiers. The amplifier 600 provides another example implementation of the control circuit 410 of amplifier 400.

In particular, the amplifier 600 includes a control circuit 610 similar to control circuit 510 including the replica current source PFET M_{RPB}, the replica input PFET M_{RP}, and the replica (diode-connected) current source NFET M_{RN} in a similar arrangement. The control circuit 610 differs from control circuit 510 in that it further includes an operational amplifier 620 including a first (e.g., positive) input coupled to the drain of the current source PFET M_{PB} (as well as the sources of the input differential PFETs M_{PP} and MPN), a second (e.g., negative) input coupled to the drain of the replica current source PFET M_{RPB} (as well as the source of the replica input PFET M_{RP}), and an output coupled to the gate of the replica input PFET M_{RPB}.

Through negative feedback, the operational amplifier 620 provides a gate voltage for the replica input PFET M_{RP} to substantially force the drain voltage of the replica current source PFET M_{RPB} (as well as the source of the replica input PFET M_{RP}) to be substantially equal to the drain voltage of the current source PFET M_{PB} (as well as the source voltages of the input differential PFETs M_{PP} and MPN). This ensures that the replica PFETs M_{RPB} and M_{RP} are biased substantially the same as the PFETs M_{PB} and MPP/M_{PN} to achieve a more accurate current generation of the replica current I_{BIASRP} based on the PFET bias current I_{BIASP}. Besides the operational amplifier 620, the operation of the control circuit 610 is substantially the same as the control circuit 510 as previously discussed.

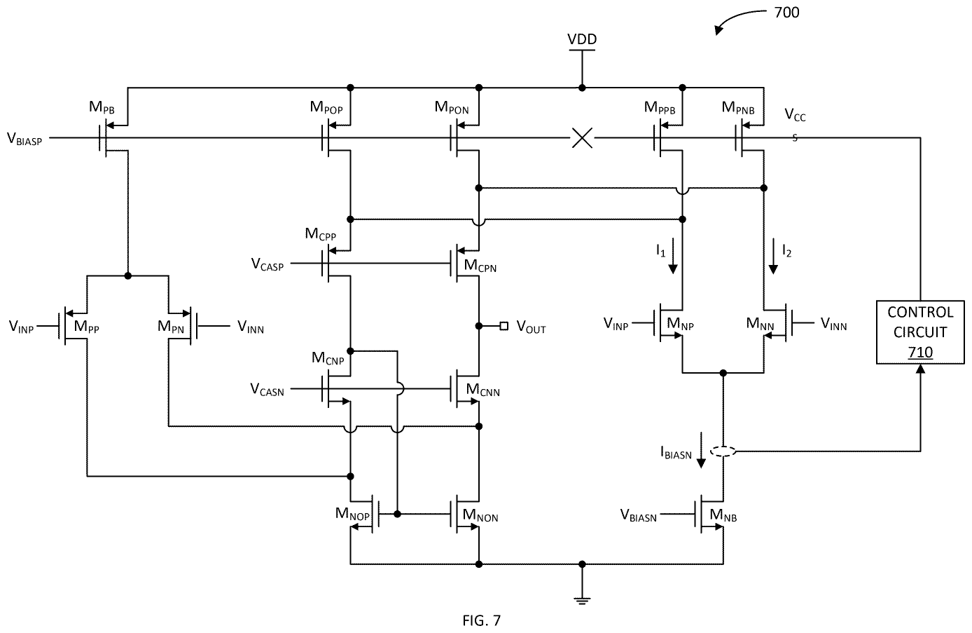

FIG. 7 illustrates a schematic diagram of another example amplifier 700 in accordance with another aspect of the disclosure. The amplifier 700 may also be an example implementation of the amplifier 220 of the LDO voltage regulator 200. The amplifier 700 is an inverted version (e.g., corresponding PFETs become NFETs, and corresponding NFETs become PFETs) of the amplifier 400.

In particular, the amplifier 700 includes a current source PFET M_{PB} including a source coupled to the upper voltage rail VDD, a gate configured to receive a PFET current source bias voltage V_{BIASP}, and a drain coupled to sources of a pair of input differential PFETs M_{PP} and M_{PN}, respectively. The PFET current source bias voltage V_{BIASP} configures the current source PFET M_{PB} to generate a substantially constant current. The input differential PFETs M_{PP} and M_{PN} include gates configured to receive a positive component V_{INP} and a negative component V_{INN} of an input differential signal V_{INP}/V_{INN}, respectively. The input differential PFETs M_{PP} and M_{PN} include drains coupled to drains of a pair of current source (or sink) NFETs M_{NOP} and M_{NON} of the output circuit of the amplifier 700, respectively.

The amplifier 700 includes an output circuit including a pair of current source PFETs M_{POP} and M_{PON} including respective sources coupled to the upper voltage rail VDD, gates coupled to the gate of current source PFET M_{PB} to also receive the PFET current source bias voltage V_{BIASP}, and drains coupled to sources of a pair of cascode PFETs M_{CPP} and M_{CPN}, respectively. The PFET current source bias voltage V_{BIASP} also configures each of the current source PFETs M_{POP} and M_{PON} to generate a substantially constant current. The cascode PFETs M_{CPP} and M_{CPN} include gates configured to receive a PFET cascode bias voltage V_{CASP}. The cascode PFETs M_{CPP} and M_{CPN} include drains coupled to drains of a pair of cascode NFETs M_{CNP} and M_{CNN}, respectively. The drains of cascode FETs M_{CPP} and M_{CNP} are coupled to gates of the current source NFETs M_{NOP} and M_{NON}. The drains of cascode FETs M_{CPN} and M_{CNN} may serve as the amplifier's 700 output to generate the output voltage V_{OUT}. The cascode NFETs M_{CNP} and M_{CNN} include gates configured to receive an NFET cascode bias voltage V_{CASN}. The cascode NFETs MCNP and M_{CNN} include sources coupled to the drains of current source NFETs M_{NOP} and M_{NON}, respectively. The current source NFETs M_{NOP} and M_{NON} include sources coupled to a lower voltage rail (e.g., ground).

The amplifier 700 further includes a pair of current source PFETs M_{PPB} and M_{PNB} including sources coupled to the upper voltage rail VDD, gates coupled to an output of a control circuit 710 to receive a gate control voltage V_{CCS}, and drains coupled to drains of a pair of input differential NFETs M_{NP} and M_{NN}, respectively. The input differential NFETs M_{NP} and M_{NN} include gates configured to receive the positive component V_{INP} and the negative component V_{INN} of the input differential signal V_{INP}/V_{INN}, respectively. The input differential NFETs M_{NP} and M_{NN} include sources coupled to a source of current source NFET M_{NB}. The current source NFET M_{NB} includes a gate configured to receive an NFET current source bias voltage V_{BIASN}, and a source coupled to the lower voltage rail (e.g., ground). The sources of cascode PFETs M_{CPP} and M_{CPN} of output circuit are coupled to the drains of current source PFETs M_{PPB} and M_{PNB}, respectively. The control circuit 710 includes an input coupled to and configured to sense the bias current I_{BIASN} through the NFET current source M_{NB}.

In the case of amplifier 700, if the control circuit 710 were not present and the gates of the current source PFETs M_{PPB} and M_{PNB} were coupled to the gates of current source PFETs M_{PB}, M_{POP}, and M_{PON}, the current source PFETs M_{PPB} and M_{PNB} would supply current to the output FETs M_{CPP}, M_{CPN}, M_{CNP} and M_{CNN} when the input common mode voltage VinCM associated with the input differential signal V_{INP}/V_{INN} is relatively low so as to collapse the current source NFET M_{NB}. As previously discussed, the higher current through the output FETs M_{CPP}, M_{CPN}, M_{CNP} and M_{CNN} causes the output resistance Rout to decrease; and consequently, the DC gain of the amplifier 700 to decrease, as previously discussed.

Thus, similarly, as discussed with reference to amplifier 400, the control circuit 710 is configured to sense the bias current I_{BIASN} flowing through the current source NFET M_{NB}, and generate the gate control voltage V_{CCS} for the current source PFETs M_{PPB} and M_{PNB} so that it generates currents I₁ and I₂ that tracks or are based on the bias current I_{BIASN}. Thus, when the input common mode voltage VinCM is relatively low, and consequently, the bias current I_{BIASN} is relatively low, the control circuit 710 is configured to generate the gate control voltage V_{CCS} to cause the current source PFETs M_{PPB} to M_{PNB} to reduce its currents I₁ and I₂ so that it does not end up flowing to the output circuit of the amplifier 700; and thus, the DC gain of the amplifier 700 remains substantially constant over a wide range of the input common mode voltage VinCM.

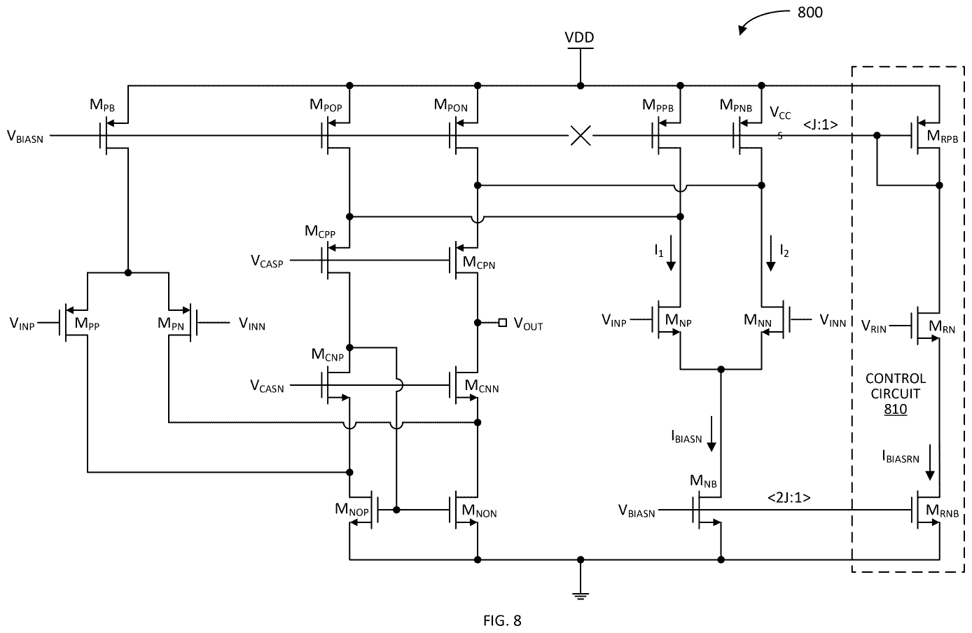

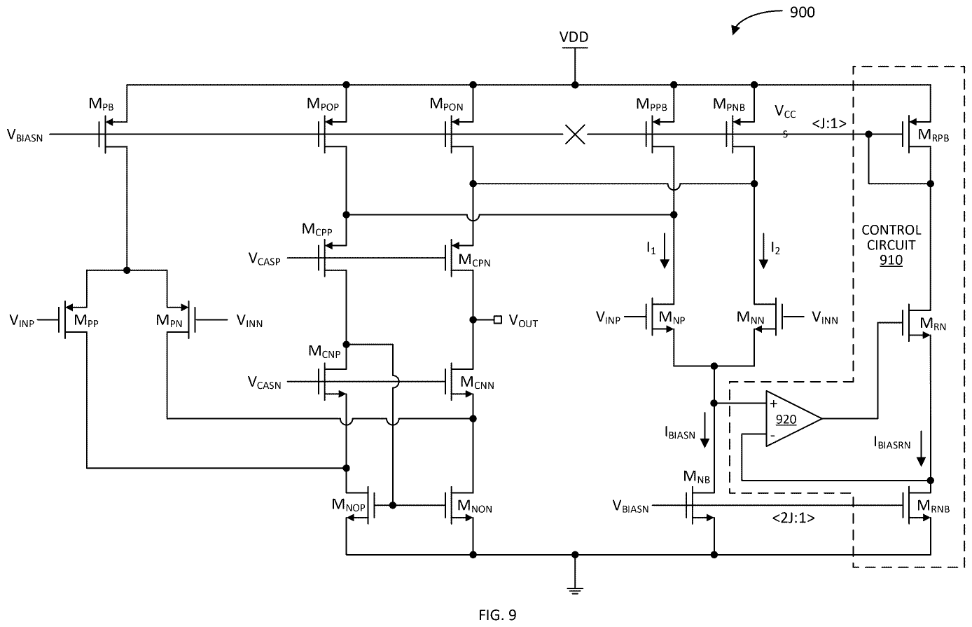

FIG. 8 illustrates a schematic diagram of another example amplifier 800 in accordance with another aspect of the disclosure. The amplifier 800 may be another example implementation of the amplifier 220 of the LDO voltage regulator 200. The amplifier 800 is similar to amplifier 700 and includes many of the same/similar elements as indicated by the same reference identifiers. The amplifier 800 provides an example implementation of the control circuit 710 of amplifier 700.

In particular, the amplifier 800 includes a control circuit 810 including a replica (diode-connected) current source PFET M_{RPB}, a replica input NFET M_{RN}, and a replica current source NFET M_{RNB}, all coupled in series between the upper voltage rail VDD and the lower voltage rail (e.g., ground). More specifically, the replica (diode-connected) current source PFET M_{RPB} includes a source coupled to the upper voltage rail VDD, a gate and a drain coupled to the gates of the current source PFETs M_{PPB} and M_{PNB}, as well as to a source of the replica input NFET M_{RN}. The replica input NFET M_{RNB} includes a gate configured to receive a replica input voltage V_{RIN}, and a source coupled to a drain of the replica current source NFET M_{RNB}. The replica current source NFET M_{RNB} includes a gate coupled to the gate of the current source NFET M_{NB} to receive the NFET current source bias voltage V_{BIASN}. The replica current source NFET M_{RNB} includes a source coupled to the lower voltage rail (e.g., ground).

The current source NFET M_{NB} and replica current source NFET M_{RNB} form a current mirror to generate a replica bias current I_{BIASRN} based on the bias current I_{BIASN}. For example, the W/L of the current source NFET M_{NB} may be substantially 2J times larger than the W/L of the replica current source NFET M_{RNB}. In such case, the replica bias current I_{BIASRN} is substantially equal to 1/2J*I_{BIASN} (e.g., the current mirror has a current gain of 1/2J). The replica input voltage V_{RIN} may be the positive component V_{INP} of the input differential signal V_{INP}/V_{INN}, the negative component V_{INN} of the input differential signal V_{INP}/V_{INN}, or substantially the common mode voltage VinCM associated with the input differential signal V_{INP}/V_{INN} (e.g., VinCM=(V_{INP}+V_{INN})/2).

The replica (diode-connected) current source PFET M_{RPB} and the current source PFETs M_{PPB} and M_{PNB} also form a current mirror to generate currents I₁ and I₂ based on the replica bias current IBIASRN. The W/L of each of the current source PFETs M_{PPB} and M_{PNB} may be substantially J times larger than the W/L of the replica (diode-connected) current source PFET M_{RPB}. In such case, the currents I₁ and I₂ are each substantially equal to 1/J*I_{BIASRN} (e.g., the current mirror has a current gain of J). Accordingly, based on the aforementioned current mirror configurations, the currents I₁ and I₂ are each substantially equal to I_{BIASN}/2 (e.g., I₁=I₂=J*I_{BIASRN}=J*(1/2J*IBIASN)=I_{BIASN}/2). As discussed with reference to amplifier 700, the currents I₁ and I₂ tracking the bias current I_{BIASN} causes the current source PFETs M_{PPB} and M_{PNB} to not substantially provide any current to the output FETs M_{CPP}, M_{CPN}, M_{CNP}, and M_{CNN} so as not to substantially affect the output resistance Rout; and therefore, the DC gain of the amplifier 800.

FIG. 9 illustrates a schematic diagram of another example amplifier 900 in accordance with another aspect of the disclosure. The amplifier 900 may be another example implementation of the amplifier 220 of the LDO voltage regulator 200. The amplifier 900 is similar to amplifier 800 and includes many of the same/similar elements as indicated by the same reference identifiers. The amplifier 900 provides another example implementation of the control circuit 710 of amplifier 700.

In particular, the amplifier 900 includes a control circuit 910 similar to control circuit 810 including the replica (diode-connected) current source PFET M_{RPB}, the replica input NFET M_{RN}, and the replica current source NFET M_{RNB} in a similar arrangement. The control circuit 910 differs from control circuit 810 in that it further includes an operational amplifier 920 including a first (e.g., positive) input coupled to the drain of the current source NFET M_{NB} (as well as the sources of the input differential NFETs M_{NP} and M_{NN}), a second (e.g., negative) input coupled to the drain of the replica current source NFET M_{RNB} (as well as the source of the replica input NFET M_{RN}), and an output coupled to the gate of the replica input NFET M_{RN}.

Through negative feedback, the operational amplifier 920 provides a gate voltage for the replica input NFET M_{RN} to substantially force the drain voltage of the replica current source NFET M_{RNB} (as well as the source voltage of the replica input NFET M_{RN}) to be substantially equal to the drain voltage of the current source NFET M_{NB} (as well as the source voltages of the input differential NFETs M_{NP} and M_{NN}). This ensures that the replica NFETs M_{RN} and M_{RNB} are biased substantially the same as the NFETs M_{NB} and M_{NP}/M_{NN} to achieve a more accurate current generation of the replica current IBIASRN based on the PFET bias current I_{BIASN}. Besides the operational amplifier 920, the operation of the control circuit 910 is substantially the same as the control circuit 810 as previously discussed.

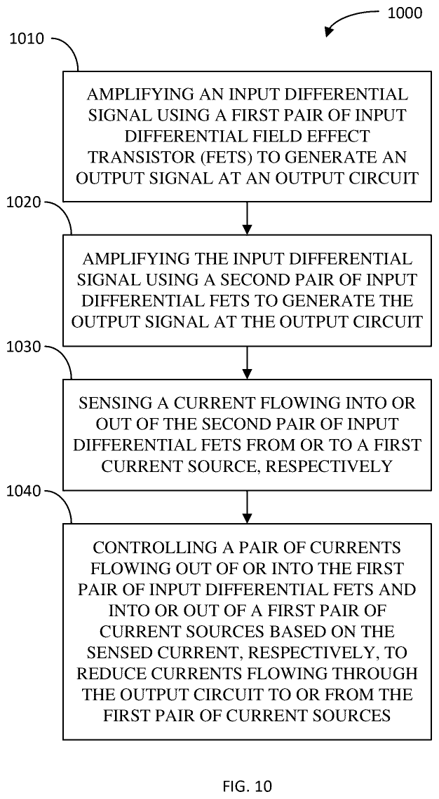

FIG. 10 illustrates a flow diagram of an example method 1000 of amplifying an input differential signal to generate an output signal in accordance with another aspect of the disclosure. The method 1000 includes amplifying an input differential signal using a first pair of input differential field effect transistor (FETs) to generate an output signal at an output circuit (block 1010). Examples of the first pair of input differential FETs include any of the input differential NFETs M_{NP}/M_{NN} of amplifiers 400, 500, and 600 or input differential PFETs MPP/M_{PN} of amplifiers 700, 800, and 900.

The method 1000 further includes amplifying the input differential signal using a second pair of input differential FETs to generate the output signal at the output circuit (block 1020). Examples of the second pair of input differential FETs include any of the input differential PFETs MPP/M_{PN} of amplifiers 400, 500, and 600 or input differential NFETs M_{NP}/M_{NN} of amplifiers 700, 800, and 900. Additionally, the method 1000 includes sensing a current flowing into or out of the second pair of input differential FETs from or to a first current source, respectively (block 1030). Examples of means for sensing a current flowing into or out of the second pair of input differential FETs from or to a first current source, respectively, include any of the control circuits 410, 510, 610, 710, 810, or 910.

The method 1000 also includes controlling a pair of currents flowing out of or into the first pair of input differential FETs and into or out of a first pair of current sources based on the sensed current, respectively, to reduce currents flowing through the output circuit to or from the first pair of current sources. Examples of means for controlling a pair of currents flowing out of or into the first pair of input differential FETs and into or out of a first pair of current sources based on the sensed current include any of the control circuits 410, 510, 610, 710, 810, or 910.

The following provides an overview of aspects of the present disclosure:

Aspect 1: An amplifier, comprising: an output circuit; a pair of input differential n-channel field effect transistors (NFETs) including drains coupled to the output circuit, and gates configured to receive positive and negative components of an input differential signal, respectively; a current source NFET including a drain coupled to sources of the input differential NFETs, and a gate coupled to the output circuit and configured to receive a first bias voltage; a current source p-channel field effect transistor (PFET) including a gate configured to receive a second bias voltage; a pair of input differential PFETs including sources coupled to a drain of the current source PFET, and gates configured to receive the positive and negative components of the input differential signal, respectively; a first pair of current source NFETs including drains coupled to the output circuit and to drains of the input differential PFETs, respectively; and a control circuit including an input coupled to the current source PFET and an output coupled to gates of the first pair of current source NFETs, respectively.

Aspect 2: The amplifier of aspect 1, wherein the control circuit includes: a replica current source PFET including a gate coupled to the gate of the current source PFET; a replica input PFET including a source coupled to a drain of the replica current source PFET, a gate configured to receive a replica input signal; and a replica current source NFET including a drain and a gate coupled to a drain of the replica input PFET and to gates of the first pair of current source NFETs.

Aspect 3: The amplifier of aspect 2, wherein the replica input PFET includes a gate configured to receive a replica input signal, the replica input signal being substantially the same as the positive component of the input differential signal, the negative component of the input differential signal, or a common mode voltage associated with the input differential signal.

Aspect 4: The amplifier of aspect 2 or 3, wherein: a channel width to channel length ratio (W/L) of the current source PFET is substantially J times greater than a W/L of the replica current source PFET; and a W/L of each of the first pair of the current source NFETs is substantially J times greater than a W/L of the replica current source NFET.

Aspect 5: The amplifier of any one of aspects 2-4, wherein the control circuit further comprises an operational amplifier including a first input coupled to the drain of the current source PFET, a second input coupled to the drain of the replica current source PFET, and an output coupled to a gate of the replica input PFET.

Aspect 6: The amplifier of any one of aspects 1-5, wherein the output circuit comprises: a pair of cascode PFETs including sources coupled to the drains of the pair of input differential NFETs, respectively, wherein the pair of cascode PFETs include gates configured to receive a first cascode bias voltage; and a pair of cascode NFETs including drains coupled to drains of the pair of cascode PFETs, wherein the pair of cascode NFETs include gates configured to receive a second cascode bias voltage, and wherein the pair of cascode NFETs include sources coupled to the drains of the first pair of current source NFETs, respectively.

Aspect 7: The amplifier of aspect 6, wherein the output circuit further comprises: a pair of current mirror PFETs including drains coupled to sources of the pair of cascode PFETs, respectively, wherein the pair of current mirror PFETs include gates coupled to the drains of one of the pair of cascode PFETs and one of the pair of cascode NFETs, respectively, wherein the drains of another of the pair of cascode PFETs and another of the pair of cascode NFETs serve as an output of the amplifier; and a second pair of current source NFETs including gates coupled to the gate of the current source NFET, wherein the second pair of current source NFETs include drains coupled to sources of the pair of cascode NFETs, respectively.

Aspect 8: An amplifier, comprising: an output circuit; a current source p-channel field effect transistor (PFET) including a gate coupled to the output circuit and configured to receive a first bias voltage; a pair of input differential PFETs including sources coupled to a drain of the current source PFET, drains coupled to the output circuit, and gates configured to receive positive and negative components of an input differential signal, respectively; a first pair of current source PFETs; a pair of input differential n-channel field effect transistors (NFETs) including drains coupled to the output circuit and to drains of the first pair of current source PFETs, respectively, and gates configured to receive the positive and negative components of the input differential signal, respectively; a current source NFET including a gate configured to receive a second bias voltage, and a drain coupled to sources of the pair of input differential NFETs, respectively; and a control circuit including an input coupled to the current source NFET and an output coupled to gates of the first pair of current source PFETs, respectively.

Aspect 9: The amplifier of aspect 8, wherein the control circuit includes: a replica current source PFET including a gate and a drain coupled to the gates of the first pair of current source PFETs; a replica input NFET including a drain coupled to the drain and the gate of the replica current source PFET; and a replica current source NFET including a drain coupled to a source of the replica input NFET and to a gate coupled to the gate of the current source NFET.

Aspect 10: The amplifier of aspect 9, wherein the replica input NFET includes a gate configured to receive a replica input signal, the replica input signal being substantially the same as the positive component of the input differential signal, the negative component of the input differential signal, or a common mode voltage associated with the input differential signal.

Aspect 11: The amplifier of aspect 9 or 10, wherein: a channel width to channel length ratio (W/L) of the current source NFET is substantially J times greater than a W/L of the replica current source NFET; and a W/L of each of the first pair of the current source PFETs is substantially J times greater than a W/L of the replica current source PFET.

Aspect 12: The amplifier of any one of aspects 9-11, wherein the control circuit further comprises an operational amplifier including a first input coupled to the drain of the current source NFET, a second input coupled to the drain of the replica current source NFET, and an output coupled to a gate of the replica input NFET.

Aspect 13: The amplifier of any one of aspects 8-12, wherein the output circuit comprises: a pair of cascode PFETs including sources coupled to the drains of the first pair of current source PFETs, respectively, wherein the pair of cascode PFETs include gates configured to receive a first cascode bias voltage; and a pair of cascode NFETs including drains coupled to drains of the pair of cascode PFETs, wherein the pair of cascode NFETs include gates configured to receive a second cascode bias voltage, and wherein the pair of cascode NFETs include sources coupled to the drains of the pair of input differential NFETs, respectively.

Aspect 14: The amplifier of aspect 13, wherein the output circuit further comprises: a second pair of current source PFETs including gates coupled to the gate of the current source PFET, wherein the second pair of current source PFETs include drains coupled to sources of the pair of cascode PFETs, respectively; and a pair of current mirror NFETs including drains coupled to sources of the pair of cascode NFETs, respectively, wherein the pair of current mirror NFETs include gates coupled to the drains of one of the pair of cascode PFETs and one of the pair of cascode NFETs, respectively, wherein the drains of another of the pair of cascode PFETs and another of the pair of cascode NFETs serve as an output of the amplifier.

Aspect 15: A method, comprising: amplifying an input differential signal using a first pair of input differential field effect transistor (FETs) to generate an output signal at an output circuit; amplifying the input differential signal using a second pair of input differential FETs to generate the output signal at the output circuit; sensing a current flowing into or out of the second pair of input differential FETs from or to a first current source, respectively; and controlling a pair of currents flowing out of or into the first pair of input differential FETs and into or out of a first pair of current sources based on the sensed current, respectively, to reduce currents flowing through the output circuit to or from the first pair of current sources.

Aspect 16: The method of aspect 15, wherein sensing the current flowing into or out of the second pair of input differential FETs comprises: generating a replica current based on the current; and generating a gate control voltage for the first pair of current sources based on the replica current.

Aspect 17: The method of aspect 16, wherein: the current is substantially 2J times greater than the replica current; and each of the pair of currents is substantially J times greater than the replica current.

Aspect 18: The method of aspect 16 or 17, further comprising: routing the replica current through a replica input FET; and providing a replica input signal to a gate of the replica input FET, wherein the replica input signal is substantially the same as a positive component of the input differential signal, a negative component of the input differential signal, or a common mode voltage associated with the input differential signal.

Aspect 19: The method of aspect 16 or 17, further comprising: routing the replica current through a replica input FET; and generating a gate voltage for the replica input FET based on a first voltage at sources of the second pair of input differential FETs and a second voltage at a source of the replica input FET.

Aspect 20: The method of any one of aspects 15-19, further comprising providing a substantially constant current from or to the output circuit.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An amplifier, comprising:
an output circuit;
a pair of input differential n-channel field effect transistors (NFETs) including drains coupled to the output circuit, and gates configured to receive positive and negative components of an input differential signal, respectively;
a current source NFET including a drain coupled to sources of the input differential NFETs, and a gate coupled to the output circuit and configured to receive a first bias voltage;
a current source p-channel field effect transistor (PFET) including a gate configured to receive a second bias voltage;
a pair of input differential PFETs including sources coupled to a drain of the current source PFET, and gates configured to receive the positive and negative components of the input differential signal, respectively;
a first pair of current source NFETs including drains coupled to the output circuit and to drains of the input differential PFETs, respectively; and
a control circuit including an input coupled to the current source PFET and an output coupled to gates of the first pair of current source NFETs.

2. The amplifier of claim 1, wherein the control circuit includes:
a replica current source PFET including a gate coupled to the gate of the current source PFET;
a replica input PFET including a source coupled to a drain of the replica current source PFET; and
a replica current source NFET including a drain and a gate coupled to a drain of the replica input PFET and to gates of the first pair of current source NFETs.

3. The amplifier of claim 2, wherein the replica input PFET includes a gate configured to receive a replica input signal, the replica input signal being substantially the same as the positive component of the input differential signal, the negative component of the input differential signal, or a common mode voltage associated with the input differential signal.

4. The amplifier of claim 2, wherein:
a channel width to channel length ratio (W/L) of the current source PFET is substantially 2J times greater than a W/L of the replica current source PFET; and
a W/L of each of the first pair of the current source NFETs is substantially J times greater than a W/L of the replica current source NFET.

5. The amplifier of claim 2, wherein the control circuit further comprises an operational amplifier including a first input coupled to the drain of the current source PFET, a second input coupled to the drain of the replica current source PFET, and an output coupled to a gate of the replica input PFET.

6. The amplifier of claim 1, wherein the output circuit comprises:
a pair of cascode PFETs including sources coupled to the drains of the pair of input differential NFETs, respectively, wherein the pair of cascode PFETs include gates configured to receive a first cascode bias voltage; and
a pair of cascode NFETs including drains coupled to drains of the pair of cascode PFETs, wherein the pair of cascode NFETs include gates configured to receive a second cascode bias voltage, and wherein the pair of cascode NFETs include sources coupled to the drains of the first pair of current source NFETs, respectively.

7. The amplifier of claim 6, wherein the output circuit further comprises:
a pair of current mirror PFETs including drains coupled to sources of the pair of cascode PFETs, respectively, wherein the pair of current mirror PFETs include gates coupled to the drains of one of the pair of cascode PFETs and one of the pair of cascode NFETs, respectively, wherein the drains of another of the pair of cascode PFETs and another of the pair of cascode NFETs serve as an output of the amplifier; and
a second pair of current source NFETs including gates coupled to the gate of the current source NFET, wherein the second pair of current source NFETs include drains coupled to sources of the pair of cascode NFETs, respectively.

8. An amplifier, comprising:
an output circuit;
a current source p-channel field effect transistor (PFET) including a gate coupled to the output circuit and configured to receive a first bias voltage;
a pair of input differential PFETs including sources coupled to a drain of the current source PFET, drains coupled to the output circuit, and gates configured to receive positive and negative components of an input differential signal, respectively;
a first pair of current source PFETs;
a pair of input differential n-channel field effect transistors (NFETs) including drains coupled to the output circuit and to drains of the first pair of current source PFETs, respectively, and gates configured to receive the positive and negative components of the input differential signal, respectively;
a current source NFET including a gate configured to receive a second bias voltage, and a drain coupled to sources of the pair of input differential NFETs, respectively; and
a control circuit including an input coupled to the current source NFET and an output coupled to gates of the first pair of current source PFETs, respectively.

9. The amplifier of claim 8, wherein the control circuit includes:
a replica current source PFET including a gate and a drain coupled to the gates of the first pair of current source PFETs;
a replica input NFET including a drain coupled to the drain and the gate of the replica current source PFET; and
a replica current source NFET including a drain coupled to a source of the replica input NFET and to a gate coupled to the gate of the current source NFET.

10. The amplifier of claim 9, wherein the replica input NFET includes a gate configured to receive a replica input signal, the replica input signal being substantially the same as the positive component of the input differential signal, the negative component of the input differential signal, or a common mode voltage associated with the input differential signal.

11. The amplifier of claim 9, wherein:
a channel width to channel length ratio (W/L) of the current source NFET is substantially 2J times greater than a W/L of the replica current source NFET; and
a W/L of each of the first pair of the current source PFETs is substantially J times greater than a W/L of the replica current source PFET.

12. The amplifier of claim 9, wherein the control circuit further comprises an operational amplifier including a first input coupled to the drain of the current source NFET, a second input coupled to the drain of the replica current source NFET, and an output coupled to a gate of the replica input NFET.

13. The amplifier of claim 8, wherein the output circuit comprises:
a pair of cascode PFETs including sources coupled to the drains of the first pair of current source PFETs, respectively, wherein the pair of cascode PFETs include gates configured to receive a first cascode bias voltage; and
a pair of cascode NFETs including drains coupled to drains of the pair of cascode PFETs, wherein the pair of cascode NFETs include gates configured to receive a second cascode bias voltage, and wherein the pair of cascode NFETs include sources coupled to the drains of the pair of input differential NFETs, respectively.

14. The amplifier of claim 13, wherein the output circuit further comprises:
a second pair of current source PFETs including gates coupled to the gate of the current source PFET, wherein the second pair of current source PFETs include drains coupled to sources of the pair of cascode PFETs, respectively; and
a pair of current mirror NFETs including drains coupled to sources of the pair of cascode NFETs, respectively, wherein the pair of current mirror NFETs include gates coupled to the drains of one of the pair of cascode PFETs and one of the pair of cascode NFETs, respectively, wherein the drains of another of the pair of cascode PFETs and another of the pair of cascode NFETs serve as an output of the amplifier.

15. A method, comprising:
amplifying an input differential signal using a first pair of input differential field effect transistor (FETs) to generate an output signal at an output circuit;
amplifying the input differential signal using a second pair of input differential FETs to generate the output signal at the output circuit;
sensing a current flowing into or out of the second pair of input differential FETs from or to a first current source, respectively; and
controlling a pair of currents flowing out of or into the first pair of input differential FETs and into or out of a first pair of current sources based on the sensed current, respectively, to reduce currents flowing through the output circuit to or from the first pair of current sources.

16. The method of claim 15, wherein sensing the current flowing into or out of the second pair of input differential FETs comprises:
generating a replica current based on the current; and
generating a gate control voltage for the first pair of current sources based on the replica current.

17. The method of claim 16, wherein:
the current is substantially 2J times greater than the replica current; and
each of the pair of currents is substantially J times greater than the replica current.

18. The method of claim 16, further comprising:
routing the replica current through a replica input FET; and
providing a replica input signal to a gate of the replica input FET, wherein the replica input signal is substantially the same as a positive component of the input differential signal, a negative component of the input differential signal, or a common mode voltage associated with the input differential signal.

19. The method of claim 16, further comprising:
routing the replica current through a replica input FET; and
generating a gate voltage for the replica input FET based on a first voltage at sources of the second pair of input differential FETs and a second voltage at a source of the replica input FET.

20. The method of claim 15, further comprising providing a substantially constant current from or to the output circuit.
